(19) United States
(12) Patent Application Publication
(10) Pub. No.: US 2026/0215308 A1
(43) Pub. Date: Jul. 23, 2026

(54) INTERCONNECT SUBSTRATE AND METHOD OF MAKING THE SAME

(71) Applicant: SHINKO ELECTRIC INDUSTRIES CO., LTD., Nagano (JP)

(72) Inventor: Ryo MIYAZAWA, Nagano (JP)

(21) Appl. No.: 19/448,818

(22) Filed: Jan. 14, 2026

(30) Foreign Application Priority Data
Jan. 20, 2025 (JP) 2025-007549

(51) Int. Cl. H10W 70/685

(52) U.S. Cl. CPC H10W 70/685

(57) ABSTRACT

An interconnect substrate includes a laminate including an insulating layer having one surface and another surface and a solder resist layer laminated on the one surface of the insulating layer, wherein the solder resist layer is an outermost insulating layer on one side of the laminate, the one side facing a same direction as the one surface of the insulating layer, wherein a peripheral portion of the solder resist layer has a cut-out extending into the insulating layer, and wherein a surface of the cut-out formed by the insulating layer is an inclined surface extending from the one surface to a side surface of the insulating layer while gradually approaching the another surface of the insulating layer in cross-sectional view.

### CROSS-REFERENCE TO RELATED APPLICATIONS

The present application is based on and claims priority to Japanese Patent Application No. 2025-007549 filed on Jan. 20, 2025, with the Japanese Patent Office, the entire contents of which are incorporated herein by reference.

### FIELD

The disclosures herein generally relate to interconnect substrates and methods of making an interconnect substrate.

### BACKGROUND

As known in the art, interconnect substrates may include interconnect layers and insulating layers. In an interconnect substrate of such a kind, for example, a solder resist layer is formed as the outermost insulating layer. The solder resist layer may be formed to cover a peripheral area of the underlying insulating layer, or may be formed without covering a peripheral area of the underlying insulating layer.

When a solder resist layer is formed while leaving the peripheral area of the underlying insulating layer exposed, there is a risk that damage such as chipping or cracking may occur in the peripheral portion of the insulating layer exposed outside the solder resist layer.

### RELATED-ART DOCUMENT

### Patent Document

[Patent Document 1] Japanese Laid-open Patent Publication No. 2011-71181

### SUMMARY

According to an aspect of the embodiment, an interconnect substrate includes a laminate including an insulating layer having one surface and another surface and a solder resist layer laminated on the one surface of the insulating layer, wherein the solder resist layer is an outermost insulating layer on one side of the laminate, the one side facing a same direction as the one surface of the insulating layer, wherein a peripheral portion of the solder resist layer has a cut-out extending into the insulating layer, and wherein a surface of the cut-out formed by the insulating layer is an inclined surface extending from the one surface to a side surface of the insulating layer while gradually approaching the another surface of the insulating layer in cross-sectional view.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a plan view illustrating an example of an interconnect substrate according to a first embodiment;

FIGS. 2A and 2B are cross-sectional views taken along the line A-A in FIG. 1;

FIG. 3 is a drawing illustrating an example of a manufacturing process of the interconnect substrate according to the first embodiment;

FIGS. 4A through 4D are drawings illustrating the example of the manufacturing process of the interconnect substrate according to the first embodiment;

FIGS. 5A and 5B are drawings illustrating the example of the manufacturing process of the interconnect substrate according to the first embodiment;

FIG. 6 is a drawing illustrating the example of the manufacturing process of the interconnect substrate according to the first embodiment;

FIG. 7 is a drawing illustrating the example of the manufacturing process of the interconnect substrate according to the first embodiment; and

FIG. 8 is a cross-sectional view illustrating an example of a semiconductor device according to the second embodiment.

### DESCRIPTION OF EMBODIMENTS

Embodiments of the invention will be described below with reference to the accompanying drawings. In these drawings, the same components are denoted by the same reference numerals, and duplicate descriptions may be omitted.

### First Embodiment

### Structure of Interconnect Substrate of First Embodiment

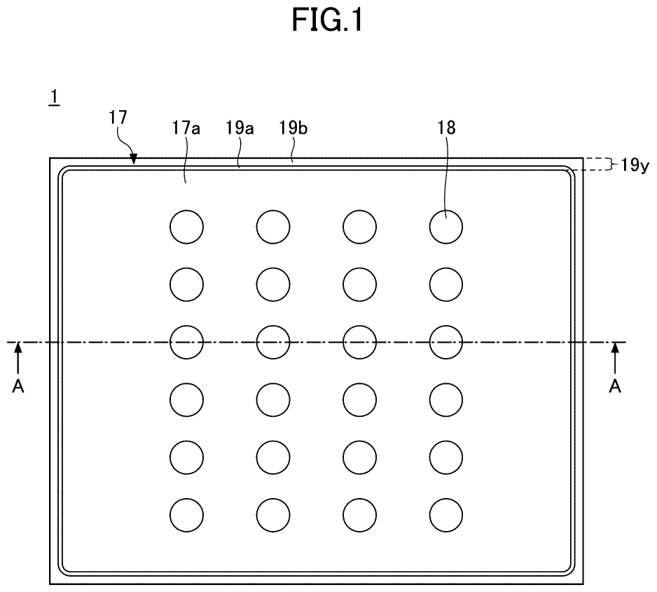

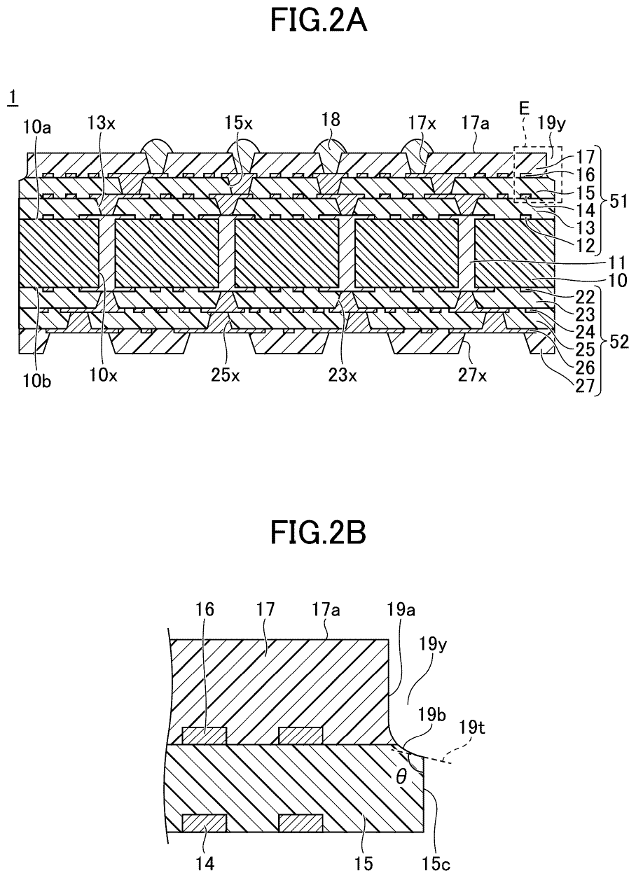

FIG. 1 is a plan view illustrating an example of an interconnect substrate according to a first embodiment; FIGS. 2A and 2B are cross-sectional views taken along the line A-A in FIG. 1. FIG. 2A is an overall view, and FIG. 2B is an enlarged cross-sectional view of the portion E in FIG. 2A.

Referring to FIG. 1 and FIGS. 2A and 2B, an interconnect substrate 1 includes a core layer 10 having a first surface 10a and a second surface 10b opposite the first surface 10a, and a first laminate 51 including interconnect layers and insulating layers alternately stacked on the first surface 10a of the core layer 10. The interconnect substrate 1 further includes a second laminate 52 including interconnect layers and insulating layers alternately stacked on the second surface 10b of the core layer 10. The interconnect substrate 1 may include external connection terminals 18. The interconnect substrate 1 may be formed to have a rectangular shape in plan view, for example.

The first laminate 51 includes an interconnect layer 12, an insulating layer 13, an interconnect layer 14, an insulating layer 15, an interconnect layer 16, and a solder resist layer 17 sequentially laminated on the first surface 10a of the core layer 10. The second laminate 52 includes an interconnect layer 22, an insulating layer 23, an interconnect layer 24, an insulating layer 25, an interconnect layer 26, and a solder resist layer 27 sequentially laminated on the second surface 10b of the core layer 10.

In the first embodiment, for convenience, the solder resist layer 17 side of the interconnect substrate 1 is referred to as an upper side or a first side, and the solder resist layer 27 side is referred to as a lower side or a second side. The surface of a portion oriented in the same direction as the solder resist layer 17 side is referred to as a first surface or an upper surface, and the surface of the portion oriented in the same direction as the solder resist layer 27 side is referred to as a second surface or a lower surface. However, the interconnect substrate 1 may be positioned upside down when used, or may be arranged at any angle. The plan view refers to the view of an object as seen from the direction normal to the first surface 10a of the core layer 10, and the plan shape refers to the shape of an object as seen from the direction normal to the first surface 10a of the core layer 10.

The core layer 10 may be formed to have a rectangular shape in plan view, for example. The core layer 10 may be, for example, a glass epoxy substrate formed by impregnating a glass cloth with an insulating resin such as an epoxy-based resin. Alternatively, the core layer 10 may be a substrate formed by impregnating a woven fabric or a nonwoven fabric of fiber such as glass fiber, carbon fiber, or aramid fiber with an epoxy-based resin or the like. The thickness of the core layer 10 is, for example, in the range of approximately 100 to 1000 μm. The core layer 10 has through holes 10x that extend through the core layer 10 in the thickness direction. The plan shape of each of the through holes 10x is, for example, circular. The diameter of each of the through holes 10x may be, for example, from 100 μm to 500 μm.

The interconnect layer 12 is disposed on the first surface 10a of the core layer 10. The interconnect layer 22 is disposed on the second surface 10b of the core layer 10. The interconnect layer 12 and the interconnect layer 22 are electrically connected to each other by through interconnects 11 formed in the through holes 10x. Each of the interconnect layers 12 and 22 is patterned in a predetermined plan shape. The interconnect layers 12 and 22 and the through interconnects 11 may be made of, for example, copper (Cu). The thicknesses of the interconnect layers 12 and 22 are, for example, in the range of approximately 10 to 40 μm. The interconnect layer 12, the interconnect layer 22, and the through interconnects 11 may be seamlessly formed.

The insulating layer 13 is an interlayer insulating layer disposed on the first surface 10a of the core layer 10 and covering the interconnect layer 12. The material of the insulating layer 13 may be, for example, an insulating resin mainly composed of an epoxy-based resin or a polyimide-based resin. The thickness of the insulating layer 13 may be, for example, in the range of approximately 30 to 40 μm. The insulating layer 13 may contain a filler such as silica (SiO₂).

Via holes 13x are formed in the insulating layer 13 to extend through the insulating layer 13 and reach the upper surface of the interconnect layer 12. The via holes 13x may each be an inverted truncated conical hole for which the diameter of the opening toward the insulating layer 15 is larger than the diameter of the opening at the upper surface of the interconnect layer 12.

The interconnect layer 14 is formed on the first side of the insulating layer 13. The interconnect layer 14 includes via interconnects filling the via holes 13x and an interconnect pattern formed on the upper surface of the insulating layer 13. The interconnect pattern is electrically connected to the interconnect layer 12 via the via interconnects. The material of the interconnect layer 14 and the thickness of the interconnect pattern may be substantially the same as those of the interconnect layer 12, for example.

The insulating layer 15 is formed on the upper surface of the insulating layer 13 so as to cover the interconnect layer 14. The material and the thickness of the insulating layer 15 may be substantially the same as those of the insulating layer 13, for example. The insulating layer 15 may contain a filler such as silica (SiO₂).

Via holes 15x are formed in the insulating layer 15 to extend through the insulating layer 15 and reach the upper surface of the interconnect layer 14. The via holes 15x may each be an inverted truncated conical hole for which the diameter of the opening toward the solder resist layer 17 is larger than the diameter of the opening at the upper surface of the interconnect layer 14.

The interconnect layer 16 is formed on the first side of the insulating layer 15. The interconnect layer 16 includes via interconnects filling the via holes 15x and pads formed on the upper surface of the insulating layer 15. The pads are electrically connected to the interconnect layer 14 through the via interconnects. The material of the interconnect layer 16 and the thickness of the pads may be substantially the same as those of the interconnect layer 12, for example. The thickness of the pads may be larger than that of the interconnect layer 12. The interconnect layer 16 may also include an interconnect pattern in addition to the pads.

The solder resist layer 17 is an outermost insulating layer on the first surface 10a side of the core layer 10, and is laminated on the upper surface of the insulating layer 15. The solder resist layer 17 covers the interconnect layer 16. The solder resist layer 17 may be formed of, for example, a photosensitive epoxy-based insulating resin or acrylic-based insulating resin. The thickness of the solder resist layer 17 is, for example, in the range of approximately 15 to 35 μm.

The solder resist layer 17 has openings 17x, and portions of the upper surface of the interconnect layer 16 are located within the openings 17x. The plan shape of each of the openings 17x may be, for example, circular. The interconnect layer 16 situated in the openings 17x may be used as pads for electrical connections with an electronic component such as a semiconductor chip, for example. That is, the interconnect substrate 1 has, on the solder resist layer 17 side, a chip mounting surface on which a semiconductor chip is mounted.

On the surface of the interconnect layer 16 exposed in the openings 17x, a metal layer may be formed, or an organic coating may be formed by applying an antioxidant treatment such as organic solderability preservative (OSP) treatment. Examples of the metal layer include an Au layer, a Ni/Au layer (a metal layer made by laminating a Ni layer and an Au layer in this order), a Ni/Pd/Au layer (a metal layer made by laminating a Ni layer, a Pd layer, and an Au layer in this order), and a Sn layer.

According to need, the external connection terminals 18 may be provided on the interconnect layer 16 exposed in the openings 17x. The external connection terminals 18 are, for example, solder bumps. The material of the solder bumps may be, for example, an alloy containing Pb, an alloy of Sn and Cu, an alloy of Sn and Ag, an alloy of Sn, Ag and Cu, or the like.

A peripheral portion of the solder resist layer 17 has a cut-out 19y formed therein that extends into the insulating layer 15. As a result, the upper surface 17a of the solder resist layer 17 is smaller than the first surface 10a of the core layer 10. For example, with the first surface 10a of the core layer 10 being rectangular in plan view, the upper surface 17a of the solder resist layer 17 is rectangular in plan view and smaller than the first surface 10a. The cut-out 19y does not penetrate the insulating layer 15.

The cut-out 19y may be provided along the entire perimeter of the solder resist layer 17. The cut-out 19y is defined by a surface 19a of the solder resist layer 17 and a surface 19b of the insulating layer 15. One end of the surface 19a joins the upper surface 17a, and the other end of the surface 19a joins one end of the surface 19b. The other end of the surface 19b meets the side surface 15c of the insulating layer 15. The surface 19a is provided in a closed-loop shape outside the upper surface 17a of the solder resist layer 17 in plan view. The surface 19b is provided in a closed-loop shape outside the surface 19a in plan view.

The surface 19b of the cut-out 19y formed by the insulating layer 15 is an inclined surface that extends toward the core layer 10 as it approaches the side surface 15c of the insulating layer 15 in cross-sectional view. That is, the thickness of the insulating layer 15 at the boundary between the surface 19b and the side surface 15c is smaller than the thickness of the insulating layer 15 at the boundary between the surface 19b and the surface 19a. The surface 19b is, for example, a concave curved surface. A region of the surface 19a located next to the insulating layer 15 may be a concave curved surface that transitions smoothly into the surface 19b in cross-sectional view. The angle θ between the surface 19b and the side surface 15c is obtuse in cross-sectional view. With the surface 19b being curved in cross-sectional view, the angle θ is defined as the angle between the side surface 15c and the tangent 19t of the surface 19b at the intersection of the surface 19b and the side surface 15c.

As described above, the interconnect substrate 1 is such that the cut-out 19y exposes the peripheral portion of the insulating layer 15 from the solder resist layer 17. However, the surface 19b of the cut-out 19y formed by the insulating layer 15 is inclined toward the core layer 10 as it approaches the side surface 15c of the insulating layer 15 in cross-sectional view, so that the angle θ between the surface 19b and the side surface 15c is obtuse. As compared with the case where the angle θ is a right angle or an acute angle, the occurrence of damage such as chipping or cracking in the periphery of the insulating layer 15 exposed from the solder resist layer 17 is effectively reduced.

The insulating layer 23 is an interlayer insulating layer disposed on the second surface 10b of the core layer 10 and covering the interconnect layer 22. The material and the thickness of the insulating layer 23 may be substantially the same as those of the insulating layer 13, for example. The insulating layer 23 may contain a filler such as silica (SiO₂).

Via holes 23x are formed in the insulating layer 23 to extend through the insulating layer 23 and reach the lower surface of the interconnect layer 22. The via holes 23x may each be a truncated conical hole for which the diameter of the opening toward the insulating layer 25 is larger than the diameter of the opening at the lower surface of the interconnect layer 22.

The interconnect layer 24 is formed on the second side of the insulating layer 23. The interconnect layer 24 includes via interconnects filling the via holes 23x and an interconnect pattern formed on the lower surface of the insulating layer 23. The interconnect pattern is electrically connected to the interconnect layer 22 through via interconnect. The material and the thickness of the interconnect layer 24 may be substantially the same as those of the interconnect layer 12, for example.

The insulating layer 25 is formed so as to cover the interconnect layer 24 on the lower surface of the insulating layer 23. The material and thickness of the insulating layer 25 may be substantially the same as those of the insulating layer 13, for example. The insulating layer 25 may contain a filler such as silica (SiO₂).

Via holes 25x are formed in the insulating layer 25 to extend through the insulating layer 25 and reach the lower surface of the interconnect layer 24. The via holes 25x may each be a truncated conical hole for which the diameter of the opening toward the solder resist layer 27 is larger than the diameter of the opening at the lower surface of the interconnect layer 24.

The interconnect layer 26 is formed on the second side of the insulating layer 25. The interconnect layer 26 includes via interconnects filling the via holes 25x and an interconnect pattern formed on the lower surface of the insulating layer 25. The interconnect pattern is electrically connected to the interconnect layer 24 through the via interconnects. The material and the thickness of the interconnect layer 26 may be substantially the same as those of the interconnect layer 12, for example.

The solder resist layer 27 is an outermost insulating layer on the second surface 10b side of the core layer 10. This solder resist layer is laminated on the lower surface of the insulating layer 25. The solder resist layer 27 covers the interconnect layer 26. The material and thickness of the solder resist layer 27 may be substantially the same as those of the solder resist layer 17, for example. The solder resist layer 27 has openings 27x, and portions of the lower surface of the interconnect layer 26 are exposed within the openings 27x. The plane shape of each of the openings 27x may be, for example, circular. The interconnect layer 26 exposed in the openings 27x may be used as pads for electrical connections to a mounting substrate such as a motherboard. If necessary, a metal layer of the kind previously described may be formed on the lower surface of the interconnect layer 26 exposed in the openings 27x, or an oxidation prevention treatment such as OSP treatment may be applied.

The solder resist layer 27 is not provided with a cut-out corresponding to the cut-out 19y. Therefore, in plan view, the peripheral portion of the solder resist layer 27 overlaps with the surface 19b of the cut-out 19y formed by the insulating layer 15. According to need, the solder resist layer 27 may be provided with a cut-out corresponding to the cut-out 19y.

### Method of Making Interconnect Substrate

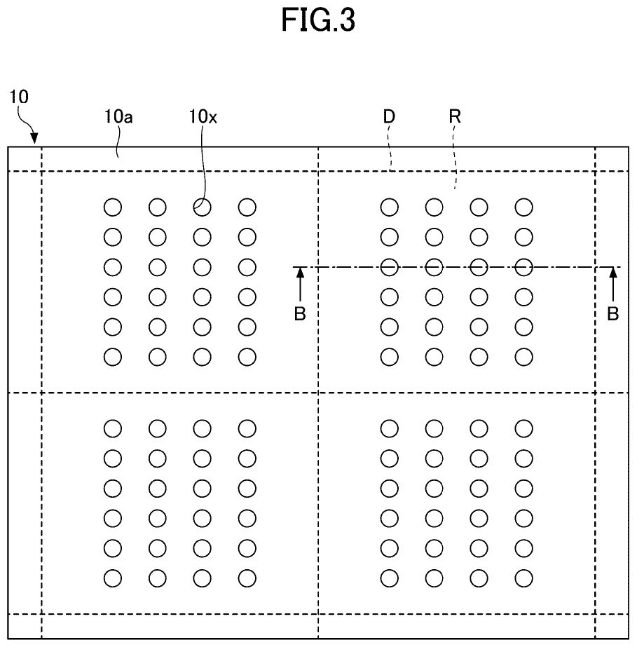

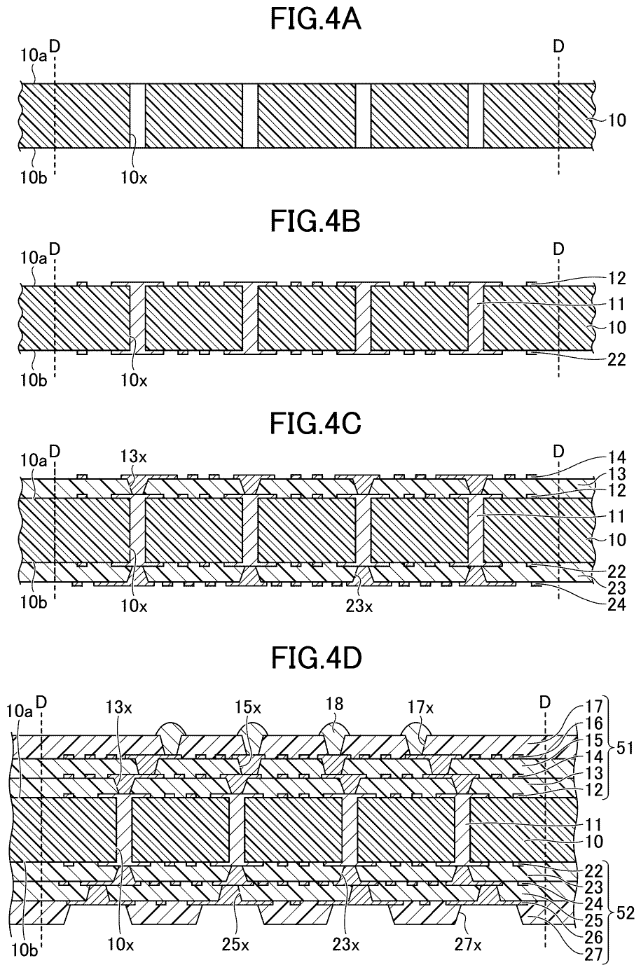

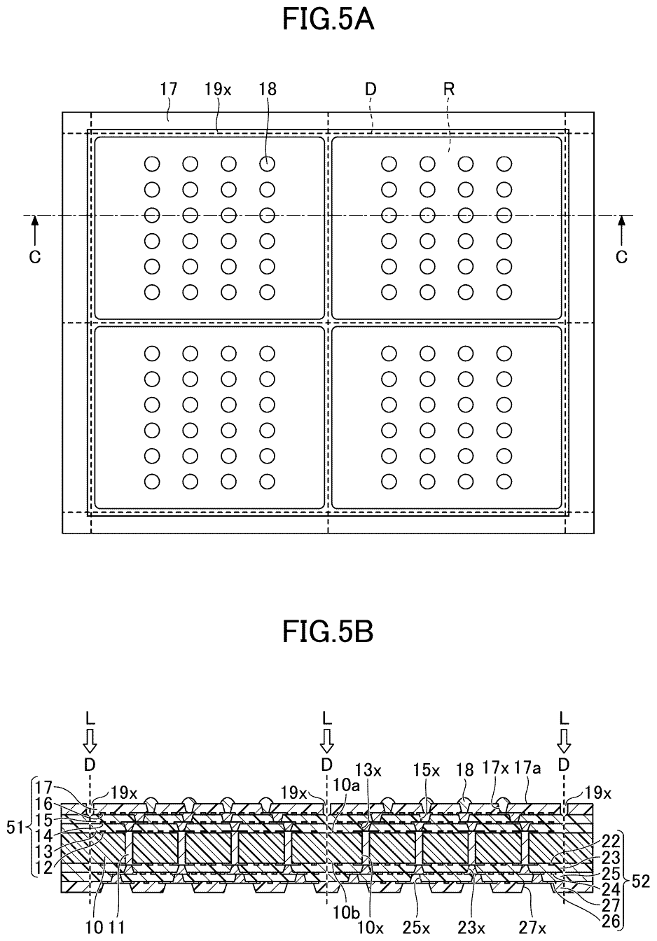

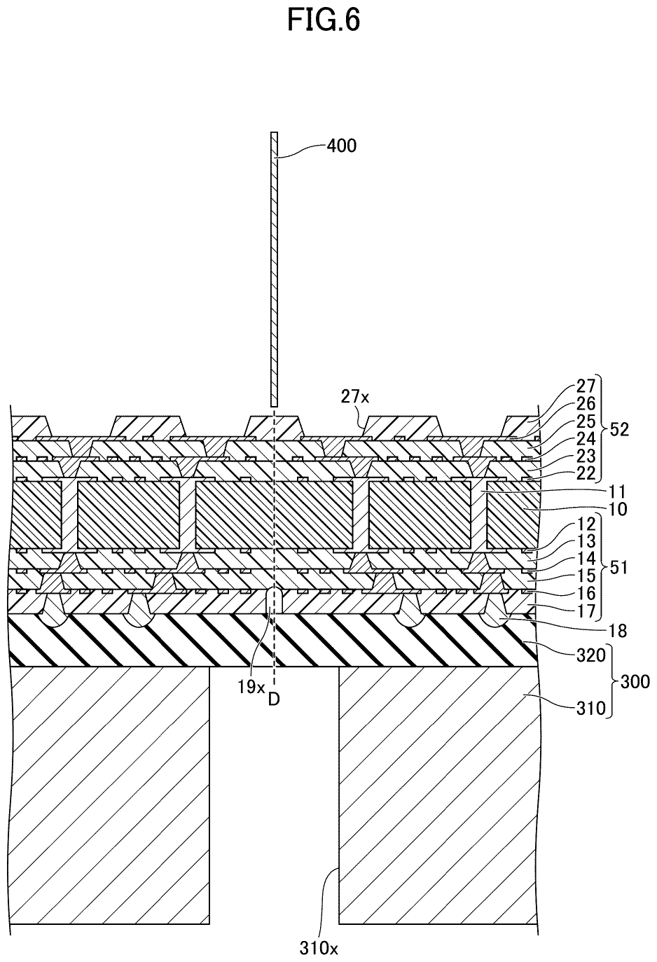

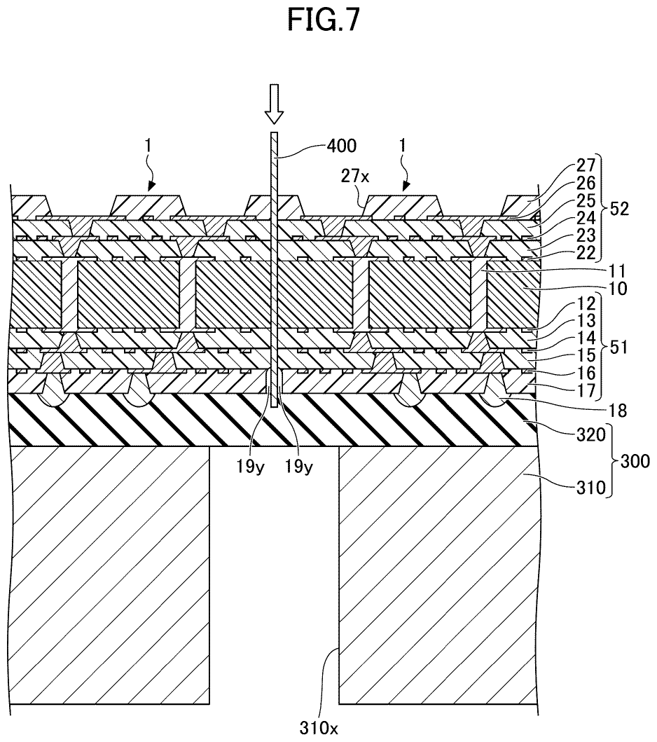

FIGS. 3 to 7 are views illustrating an example of a manufacturing process of the interconnect substrate according to the first embodiment. Specifically, FIGS. 3 and 5A are plan views, and FIGS. 4A through 4D are cross-sectional views corresponding to FIG. 2A and taken along the line B-B in FIG. 3. FIG. 5B is a cross-sectional view taken along the line C-C in FIG. 5A. FIGS. 6 and 7 are enlarged cross-sectional views of a portion of what is illustrated in FIG. 5B, but are drawn upside down relative to FIG. 5B.

First, in a step illustrated in FIGS. 3 and 4A, a core layer 10 is prepared. The core layer 10 includes a plurality of interconnect regions R for singulation into interconnect substrates, and cutting regions D along which cuts are to be made for singulation. Although the cutting regions D are illustrated by lines in FIGS. 3 and 4A, they may each be a region having a constant width. Next, through holes 10x extending from the first surface 10a to the second surface 10b are formed in the core layer 10 inside each interconnect region R. The through holes 10x may be formed by, for example, laser processing, drilling, wet etching, or the like.

In steps illustrated in FIGS. 4B through 4D, a first laminate 51 including alternately laminated interconnect layers and insulating layers is formed on the first surface 10a of the core layer 10. Further, a second laminate 52 including alternately laminated interconnect layers and insulating layers is formed on the second surface 10b of the core layer 10. Specifically, as illustrated in FIG. 4B, an interconnect layer 12 is disposed in each interconnect region R on the first surface 10a of the core layer 10, and an interconnect layer 22 is disposed in each interconnect region R on the second surface of the core layer 10, with through interconnects 11 formed in the through holes 10x. For example, a seed layer (copper or the like) covering the first surface 10a, the second surface 10b of the core layer 10, and the inner wall surfaces of the through holes 10x is formed by an electroless plating method, a sputtering method, or the like, and an electroplating layer (copper or the like) is formed on the seed layer by an electroplating method using the seed layer as a current supply path. This arrangement fills the through holes 10x with the electrolytic plating layer formed on the seed layer, and forms a conductive layer as a laminate of the seed layer and the electrolytic plating layer on each of the first surface 10a and the second surface 10b of the core layer 10. Thereafter, the conductor layers are patterned into predetermined plan shapes by a subtractive method or the like to form the interconnect layers 12 and 22.

As illustrated in FIG. 4C, insulating layers 13 and 23 and interconnect layers 14 and 24 are formed. First, the insulating layer 13 covering the upper surface of the interconnect layer 12 is disposed in each interconnect region R and each cutting region D on the first surface 10a of the core layer 10. Specifically, for example, a semi-cured epoxy-based resin film or the like is laminated on the first surface 10a of the core layer 10 so as to cover the interconnect layer 12, and then cured to form the insulating layer 13. Alternatively, instead of laminating epoxy-based resin film or the like, epoxy-based resin or the like in liquid or paste form may be applied and then cured to form the insulating layer 13. The material and the thickness of the insulating layer 13 are as previously described. Similarly, the insulating layer 23 covering the lower surface of the interconnect layer 22 is disposed in each interconnect region R and each cutting region D on the second surface 10b of the core layer 10.

Next, via holes 13x are formed in the insulating layer 13 to penetrate the insulating layer 13 and expose the upper surface of the interconnect layer 12. Further, via holes 23x are formed in the insulating layer 23 to penetrate the insulating layer 23 and expose the lower surface of the interconnect layer 22. The via holes 13x and 23x may be formed by, for example, laser processing using a CO₂ laser or the like. After the via holes 13x and 23x are formed, desmearing treatment is preferably performed to remove resin residues adhering to the surfaces of the interconnect layers 12 and 22 exposed at the end of the via holes 13x and 23x.

The interconnect layer 14 is then formed on the first side of the insulating layer 13. The interconnect layer 14 includes via interconnects filling the via holes 13x and an interconnect pattern formed on the upper surface of the insulating layer 13. The interconnect layer 14 is electrically connected to the interconnect layer 12 exposed at the bottom of the via holes 13x. Similarly, an interconnect layer 24 is formed on the second side of the insulating layer 23. The interconnect layer 24 includes via interconnects filling the via holes 23x and an interconnect pattern formed on the lower surface of the insulating layer 23. The interconnect layer 24 is electrically connected to the interconnect layer 22 exposed at the end of the via holes 23x. The materials of the interconnect layers 14 and 24 and the thicknesses of the interconnect patterns may be substantially the same as those of the interconnect layer 12, for example. The interconnect layers 14 and 24 are formed, for example, by a semi-additive method.

As illustrated in FIG. 4D, insulating layers 15 and 25, interconnect layers 16 and 26, solder resist layers 17 and 27, and external connection terminals 18 are formed. First, substantially the same steps as those of FIG. 4C are repeated to form the insulating layers 15 and 25 and the interconnect layers 16 and 26. Next, the solder resist layer 17 is formed on the upper surface of the insulating layer 15 so as to cover the interconnect layer 16. Further, a solder resist layer 27 is formed on the lower surface of the insulating layer 25 so as to cover the interconnect layer 26. The solder resist layer 17 may be formed, for example, by applying a photosensitive epoxy-based insulating resin in liquid or paste form to the upper surface of the insulating layer 15 so as to cover the interconnect layer 16 by screen printing, roll coating, spin coating, or the like. Alternatively, a photosensitive epoxy-based insulating resin film, for example, may be laminated on the upper surface of the insulating layer 15 so as to cover the interconnect layer 16. The method of forming the solder resist layer 27 is substantially the same as that of the solder resist layer 17. Thereafter, the solder resist layers 17 and 27 are exposed and developed. As a result, openings 17x are formed through the solder resist layer 17 to expose the interconnect layer 16. Also, openings 27x for exposing portions of the lower surface of the interconnect layer 26 are formed in the solder resist layer 27. According to need, the external connection terminals 18 may be provided on the interconnect layer 16 exposed in the openings 17x. The external connection terminals 18 are, for example, solder bumps formed by solder reflow or the like.

In the step illustrated in FIGS. 5A and 5B, the solder resist layer 17 is irradiated with laser light L, so that grooves 19x, each straddling a corresponding cutting region D, are formed so as to penetrate the solder resist layer 17. The grooves 19x are formed along the cutting regions D, which segment the interconnect regions R, and throughout the cutting regions D. The grooves 19x may or may not be formed along the cutting regions D that do not segment the interconnect regions R. The grooves 19x divide the solder resist layer 17 into separate regions located in the respective interconnect regions R. The grooves 19x penetrate the solder resist layer 17 to extend into the insulating layer 15, but do not penetrate the insulating layer 15. The bottoms of the grooves 19x each have a curved surface in which a central region is lower than the side regions. The bottoms of the grooves 19x each have, for example, a concave curved surface. The grooves 19x may be formed by, for example, a CO₂ laser or the like.

In the step illustrated in FIG. 6, a mounting table 300 is prepared that includes a base plate 310 with an opening 310x and a rubber pad 320 arranged on the base plate 310 so as to close the opening 310x. Then, the structure illustrated in FIG. 5B having the grooves 19x is arranged on the mounting table 300 with the solder resist layer 17 facing downward. The structure illustrated in FIG. 5B may be steadily held on the mounting table 300 by vacuum suction or the like. The structure illustrated in FIG. 5B is arranged such that the grooves 19x are aligned with the opening 310x. Then, a blade 400 having a width narrower than each groove 19x is arranged directly above a given groove 19x. For example, the width of the blade 400 may be approximately 0.1 mm smaller than the width of the groove 19x. Since the rubber pad 320 is an elastic body, the presence of the external connection terminals 18 projecting from the solder resist layer 17 does not hinder the placement of the structure on the mounting table 300 with the solder resist layer 17 facing downward.

In the step illustrated in FIG. 7, the blade 400 is lowered toward the mounting table 300 as shown by the arrow, and the structure illustrated in FIG. 6 is cut along the cutting region D, thereby producing a plurality of singulated interconnect substrates 1. The blade 400 first cuts the solder resist layer 27, and then moves toward the solder resist layer 17 by cutting the subsequent layers, thereby dividing the structure illustrated in FIG. 6 without contacting the solder resist layer 17 surrounding the groove 19x. The cutting divides each groove 19x, so that the cut-out 19y extending into the insulating layer 15 is provided along the periphery of the solder resist layer 17 of each singulated interconnect substrate 1. The surface 19b of the cut-out 19y formed by the insulating layer 15 is inclined toward the core layer 10 as it approaches the side surface 15c of the insulating layer 15 in cross section. The inclined surface is, for example, a curved surface. As the blade 400, for example, a rotary blade may be used.

As described above, the manufacturing process of the interconnect substrate 1 includes orienting the solder resist layer 17 provided with the grooves 19x toward the mounting table 300, and cutting from the solder resist layer 27 side with the blade 400. This prevents chipping of the solder resist layer 17 at the time of cutting.

If the grooves 19x were not provided, the blade 400 penetrating the solder resist layer 17 would impose a downward delaminating force on the portion of the solder resist layer 17 in contact with the blade 400. As a result, the portion of the solder resist layer 17 would delaminate from the insulating layer 15 in some instances, thereby causing chipping.

In contrast, the manufacturing process of the interconnect substrate 1 provides the grooves 19x penetrating the solder resist layer 17 and straddling the cutting regions D, and performs cutting by using the blade 400 having a width narrower than each groove 19x. Since the blade 400 does not come into contact with the solder resist layer 17, a downward delaminating force is not applied to the solder resist layer 17 at the time of cutting, thereby keeping the solder resist layer 17 free from chipping. Further, a force applied to the solder resist layer 27 at the time of cutting is a pressing force toward the insulating layer 25, chipping does not occur even without the provision of grooves.

Alternatively, the grooves may not be provided in the solder resist layer 17 but formed in the solder resist layer 27, and cutting may be performed by orienting the solder resist layer 27 downward on the mounting table 300. This arrangement effectively prevents the solder resist layer 27 from chipping at the time of cutting.

Nonetheless, cutting is preferably performed by providing the solder resist layer 17 with the grooves 19x and orienting the solder resist layer 17 downward on the mounting table 300. The solder resist layer 17 side is a chip mounting surface which receives a semiconductor chip, and, thus, has the external connection terminals 18 having a relatively narrow pitch. Therefore, when the solder resist layer 27 is provided with grooves and cutting is performed from the solder resist layer 17 side, foreign matter such as shavings generated at the time of cutting may enter the spaces between the adjacent external connection terminals 18 and may stick there. Such a problem is effectively avoided by providing the solder resist layer 17 with the grooves 19x and orienting the solder resist layer 17 downward on the mounting table 300 for cutting.

### Second Embodiment

The second embodiment is directed to an example of a semiconductor device in which a semiconductor chip is mounted on the interconnect substrate according to the first embodiment. It may be noted that, in connection with the second embodiment, descriptions of the same components as those in the already described embodiment may be omitted.

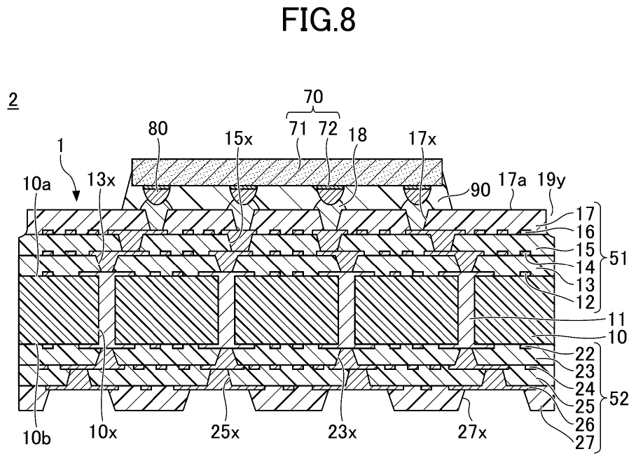

FIG. 8 is a cross-sectional view illustrating an example of a semiconductor device according to the second embodiment. Referring to FIG. 8, a semiconductor device 2 includes the interconnect substrate 1 illustrated in FIG. 1, a semiconductor chip 70, bumps 80, and an underfill resin 90.

The semiconductor chip 70 includes a chip 71 and electrodes 72. The chip 71 is configured such that a semiconductor integrated circuit (not illustrated) or the like is formed on a thin semiconductor substrate (not illustrated) made of, for example, silicon. The electrodes 72 electrically connected to the semiconductor integrated circuit are formed on the semiconductor substrate (not illustrated).

The bumps 80 are formed on the electrodes 72 of the semiconductor chip 70, and electrically connect the electrodes 72 and the external connection terminals 18 of the interconnect substrate 1. The electrodes 72 may be formed of, for example, copper. The bumps 80 are, for example, solder bumps. The material of the solder bumps may be, for example, an alloy containing Pb, an alloy of Sn and Cu, an alloy of Sn and Ag, an alloy of Sn, Ag and Cu, or the like. The underfill resin 90 fills a gap between the semiconductor chip 70 and the upper surface of the solder resist layer 17 of the interconnect substrate 1.

In this manner, the fabrication of a semiconductor device is effectively achieved by mounting the semiconductor chip on the interconnect substrate according to the first embodiment.

Although the preferred embodiments have been described in detail above, the above-described embodiments are non-limiting examples, and various modifications and substitutions may be made to the above-described embodiments without departing from the scope of the claims.

For example, the above-described embodiments are directed to the interconnect substrate that has the first laminate on the first surface of the core layer and the second laminate on the second surface. However, the present invention may be applied to an interconnect substrate having the first laminate on the first surface of the core layer and not having the second laminate on the second surface, while providing substantially the same advantageous effects. In the case where the interconnect substrate does not have the second laminate, the through holes may not be provided in the core layer. The present invention is also applicable to a coreless substrate having no core layer.

According to at least one embodiment, an interconnect substrate is provided that effectively suppresses the occurrence of damage in the peripheral portion of the insulating layer exposed outside the solder resist layer.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

The disclosures herein non-exhaustively include the subject matter set forth in the following clauses.
Clause 1. A method of making an interconnect substrate, comprising:
forming a laminate having a plurality of interconnect regions for singulation into interconnect substrates and cutting regions along which cuts are to be made for the singulation, the laminate including an insulating layer having one surface and another surface and a solder resist layer laminated on the one surface of the insulating layer;
forming grooves each penetrating the solder resist layer and each straddling a corresponding one of the cutting regions by irradiating the solder resist layer with laser light;
arranging the laminate having the grooves formed therein on a mounting table with the solder resist layer facing downward; and
producing a plurality of singulated interconnect substrates by cutting the laminate along the cutting regions by lowering a blade having a width narrower than each of the grooves toward the mounting table.
Clause 2. The method according to clause 1, wherein in the forming of the grooves, the grooves penetrate the solder resist layer and extend into the insulating layer.
Clause 3. The method according to clause 2, wherein in the producing of the plurality of singulated interconnect substrates, a cut-out extending into the insulating layer is formed along a periphery of the solder resist layer of each of the singulated interconnect substrates, and
wherein a surface of the cut-out formed by the insulating layer is an inclined surface extending to the side surface of the insulating layer while gradually approaching the another surface of the insulating layer in cross section.
Clause 4. The method according to clause 3, wherein the inclined surface is a curved surface.
Clause 5. The method according to clause 1, wherein a side of the laminate where the solder resist layer is provided is a chip mounting surface configured to have a semiconductor chip mounted thereon.
Clause 6. The method according to clause 1, further comprising:
providing a core layer having one surface and another surface;
forming the laminate on the one surface of the core layer; and
forming, on the another surface of the core layer, a second laminate including a second insulating layer having one surface and another surface and a second solder resist layer laminated on the another surface of the second insulating layer,
wherein the second solder resist layer is an outermost insulating layer on a side of the second laminate toward which the another surface of the second insulating layer faces, and
wherein in the cutting of the laminate, the blade cuts the second solder resist layer to move toward the solder resist layer.

What is claimed is:

1. An interconnect substrate comprising:
a laminate including an insulating layer having one surface and another surface and a solder resist layer laminated on the one surface of the insulating layer,
wherein the solder resist layer is an outermost insulating layer on one side of the laminate, the one side facing a same direction as the one surface of the insulating layer,
wherein a peripheral portion of the solder resist layer has a cut-out extending into the insulating layer, and
wherein a surface of the cut-out formed by the insulating layer is an inclined surface extending from the one surface to a side surface of the insulating layer while gradually approaching the another surface of the insulating layer in cross-sectional view.

2. The interconnect substrate according to claim 1, wherein the inclined surface is a curved surface.

3. The interconnect substrate according to claim 1, wherein the one side of the laminate is a chip mounting surface configured to have a semiconductor chip mounted thereon.

4. The interconnect substrate according to claim 1, further comprising:
a core layer having one surface and another surface, the one surface of the core layer having the laminate disposed thereon; and
a second laminate provided on the another surface of the core layer,
wherein the second laminate includes a second insulating layer having one surface and another surface and a second solder resist layer laminated on the another surface of the second insulating layer,
wherein the second solder resist layer is an outermost insulating layer on one side of the second laminate, the one side of the second laminate facing a same direction as the another surface of the second insulating layer, and
wherein in plan view, a peripheral portion of the second solder resist layer overlaps with the surface of the cut-out formed by the insulating layer.
